(19) United States
(12) Patent Application Publication
(10) Pub. No.: US 2026/0030426 A1
(43) Pub. Date: Jan. 29, 2026

(54) ANALOGUE CIRCUIT DESIGN

(71) Applicant: Agile Analog Ltd, Cambridge (GB)

(72) Inventor: Michael Hulse, Cambridge (GB)

(21) Appl. No.: 18/997,174

(22) PCT Filed: Jul. 24, 2023
(86) PCT No.: PCT/GB2023/051950

§ 371 Date: Jan. 20, 2025

(30) Foreign Application Priority Data
Jul. 26, 2022 (GB) 2210918.5

(51) Int. Cl. G06F 30/367; G06F 30/27; G06F 30/373

(52) U.S. Cl. CPC G06F 30/367; G06F 30/27; G06F 30/373

(57) ABSTRACT

An analogue circuit design apparatus is configured to receive information representing electrical requirements for the analogue circuit, identify a plurality of potential layout techniques such as symmetrical, common centroid, and interdigitated layout technique, select one of the potential layout technique as the current selected layout technique, and determine physical properties of the analogue circuit based on the electrical requirements and the current selected layout technique. The analogue circuit design apparatus is configured to determine whether the current selected layout technique and determined physical properties of the analogue circuits meet the electrical requirements, and in the event that they do meet the electrical requirements, produce and output a design, or if they do not meet the electrical requirements, to repeat the process with a different selected layout technique as the current selected layout technique.

### FIELD OF THE INVENTION

The present disclosure relates to methods and systems for analogue circuit design, and in particular, methods and systems for automating the design process for analogue circuits.

### BACKGROUND

Analogue components cause the most chip production test failures and up to 95% of field failures. While circuit design for digital circuits has become automated to some degree in recent times, the automation of analogue circuit design has proven problematic, not least due to e.g., parasitic effects. Conventional approaches to analogue circuit design might involve “best guess” estimates or specification guard-banding performed manually by engineering teams relying on prior knowledge and experience, often with the result that circuits are over-engineered and inefficient, or prone to failure. There is therefore a desire to create a more efficient and reliable process for designing analogue circuits.

### SUMMARY OF THE INVENTION

Aspects of the invention are as set out in the independent claims and optional features are set out in the dependent claims. Aspects of the invention may be provided in conjunction with each other and features of one aspect may be applied to other aspects.

In a first aspect there is provided an analogue circuit design apparatus for at least partly automating the design of analogue circuits. At a high level, the analogue circuit design apparatus is configured to obtain electrical requirements required of a desired circuit (e.g., input by a user), select potential “legal” layouts that could be employed to design the circuit, and then select physical properties of that circuit to satisfy both electrical requirements and legal layouts.

Advantageously, embodiments of the analogue circuit design apparatus and method can design analogue circuits the determine the optimum layout and physical properties of an analogue circuit based on the designer's intent for that circuit, as dictated by the electrical requirements. Moreover, embodiments of the analogue circuit design apparatus can optimise the use of silicon, for example, and minimise variations and parasitics.

In more detail, the analogue circuit design apparatus comprises at least one design unit comprising a processor and a communications interface. The processor is configured to:
(a) control the communications interface to receive information representing electrical requirements for the analogue circuit or a portion thereof;
(b) identify, based on the received information, a plurality of potential layouts of the analogue circuit or portion thereof that satisfy the electrical requirements;
(c) select one of the plurality of potential layouts as the current selected layout, and determine physical properties of the analogue circuit or portion thereof based on the electrical requirements and the selected one of the plurality of potential layouts;
(d) determine whether the current selected layout and determined physical properties of the analogue circuit or portion thereof meet the electrical requirements;
(e) in the event that the current selected layout and determined physical properties of the analogue circuit or portion thereof meet the electrical requirements, produce an output design for the analogue circuit or portion thereof; and
(f) in the event that the selected layout and determined physical properties of the analogue circuit or portion thereof do not meet the electrical requirements:
   (f1) select another one of the plurality of potential layouts as the current selected layout and determine physical properties of the analogue circuit or portion thereof based on the electrical requirements and the selected one of the plurality of potential layouts;
   (f2) determine whether the current selected layout and determined physical properties of the analogue circuit or portion thereof meet the electrical requirements;
   (f3) and repeat steps (f1) and (f2) until the current selected layout and determined physical properties of the analogue circuit or portion thereof meet the electrical requirements, and then produce an output design for the analogue circuit or portion thereof.

Determining physical properties of the analogue circuit may comprise determining the physical size and/or spacing of components for implementing the electrical requirements.

Determining layout requirements for the analogue circuit may comprise identifying a layout technique from a list of possible layout techniques for implementing the electrical requirements. The list of possible layout techniques may comprise, for example: symmetrical, common centroid, and interdigitated.

Identifying, based on the received information, a plurality of potential layouts of the analogue circuit or portion thereof that satisfy the electrical requirements, may comprise ascribing functionality to portions of the analogue circuit based on the electrical requirements, and identifying potential analogue circuit layouts that provide the ascribed functionality. In other words, the analogue circuit design apparatus may be configured to break down the circuit into functional blocks and determine optimal layout technique for each of these functional blocks-for example, the analogue circuit design apparatus may determine that common centroid is the layout technique to apply if designing a differential pair, and may determine that current sources need to be interdigitated.

Identifying a plurality of potential layouts of the analogue circuit or portion therefore that satisfy the electrical requirements may comprise obtaining at least one layout for at least a portion of the analogue circuit via the communications interface. For example, the designer may specify which layout technique to apply to parts/portions or all of the analogue circuit that is to be designed. Advantageously, the analogue circuit design apparatus of embodiments of the claim allow the intent and context to be taken into account when designing the analogue circuit, which has not hitherto been possible.

The selection of the layout at step (c) and/or step (f1) may be based on a prioritisation of the plurality of potential layouts forming a prioritised list of potential layouts for the analogue circuit or portion thereof. The prioritisation may, for example, be specified by a user/designer (and received as an input via the communications interface, for example), or may be determined e.g., by learning such as deep learning and/or based on previous circuit designs that have been created.

Likewise, the determination of physical properties of the analogue circuit or a portion thereof at step (c) and/or step (f1) may be based on a prioritisation of the physical properties forming a prioritised list of physical properties for the analogue circuit or portion thereof. The prioritisation may, for example, be specified by a user/designer (and received as an input via the communications interface, for example), or may be determined e.g., by learning such as deep learning and/or based on previous circuit designs that have been created.

In some examples the processor is further configured to:
control the communications interface to receive information representing physical requirements for the analogue circuit or a portion thereof; and
determine physical properties of the analogue circuit or portion thereof based on the electrical requirements, the physical requirements and the selected one of the plurality of potential layouts.

In some examples the processor is further configured to:
(g) determine, for each current design for the analogue circuit, how well the current design meets the electrical requirements;
(h) select, a further analogue circuit design architecture as the current analogue circuit design architecture;
(i) repeat steps (b) and (f) to produce a plurality of produced output designs; and
(j) select and output a design for the analogue circuit from the plurality of produced analogue circuit designs that at least one of:
   (i) best meets the electrical requirements;
   (ii) makes the most efficient use of silicon; and
   (iii) has the lowest variation in electrical properties.

In some examples the apparatus comprises a primary design unit and a secondary design unit,
wherein the primary design unit is configured to:
   divide the analogue circuit or portion thereof into respective circuit portions based on the current selected layout;
   provide electrical requirements for each circuit portion to at least one of a plurality of secondary design units;
and wherein each of the plurality of secondary design units of the analogue circuit design apparatus is configured to:
   design a respective circuit portion of the plurality of circuit portions based on the electrical requirements for that respective circuit portion provided by the primary design unit; and
   output a resulting initial design of the respective circuit portion;
and wherein the primary design unit is further configured to:
   receive a respective design for each circuit portion from each of the plurality of secondary design units; and
   determine whether the respective design for each circuit portion from each of the plurality of secondary design units meets the electrical requirements;
   in the event that the respective design for each circuit portion meets the electrical requirements, produce an output design for the analogue circuit or portion thereof; and
   produce the current analogue circuit design for the analogue circuit that satisfies the electrical requirements based on the respective designs for each circuit portion from each of the secondary design units.

The apparatus may comprise a primary design unit and a secondary design, wherein the primary design unit is configured to:
(aa) identify, based on the received information, a plurality of potential layouts of the analogue circuit or portion thereof that satisfy the electrical requirements;
(ab) select one of the plurality of potential layouts as the current selected layout;
(ac) divide the analogue circuit or portion thereof into respective circuit portions based on the current selected layout and/or physical properties;
(ad) provide electrical requirements for each circuit portion to at least one of a plurality of secondary design units;
   and wherein each of the plurality of secondary design units of the analogue circuit design apparatus is configured to:
(ae) receive information representing electrical requirements for the analogue circuit or a portion thereof;
(af) identify, based on the received information, a plurality of potential layouts of the corresponding respective portion of the analogue circuit that satisfy the electrical requirements;
(ag) select one of the plurality of potential layouts as the current selected layout, and determine physical properties of the analogue circuit or portion thereof based on the electrical requirements and the selected one of the plurality of potential layouts;
(ah) determine whether the current selected layout and determined physical properties of the analogue circuit or portion thereof meet the electrical requirements;
(ai) output a resulting initial design of the respective circuit portion; and wherein the primary design unit is further configured to:

(aj) receive a respective design for each circuit portion from each of the plurality of secondary design units; and
(ak) determine whether the respective design for each circuit portion from each of the plurality of secondary design units meets the electrical requirements and/or has the necessary physical properties;
in the event that the respective design for each circuit portion meets the electrical requirements:
(al) produce an output design for the analogue circuit or portion thereof; and
(am) produce the current analogue circuit design for the analogue circuit that satisfies the electrical requirements based on the respective designs for each circuit portion from each of the secondary design units.

The apparatus may comprise a primary design unit and a secondary design, wherein the primary design unit is configured to
(aa) identify, based on the received information, a plurality of potential layouts of the analogue circuit or portion thereof that satisfy the electrical requirements;
(ab) select one of the plurality of potential layouts as the current selected layout, determine physical properties of the analogue circuit or portion thereof based on the electrical requirements and the selected one of the plurality of potential layouts;
(ac) divide the analogue circuit or portion thereof into respective circuit portions based on the current selected layout and/or physical properties;
(ad) provide electrical requirements and/or physical properties for each circuit portion to at least one of a plurality of secondary design units; and wherein each of the plurality of secondary design units of the analogue circuit design apparatus is configured to:
(ae) receive information representing electrical requirements for the analogue circuit or a portion thereof;
(af) identify, based on the received information, a plurality of potential layouts of the corresponding respective portion of the analogue circuit that satisfy the electrical requirements;

(ag) select one of the plurality of potential layouts as the current selected layout, and determine physical properties of the analogue circuit or portion thereof based on the electrical requirements and the selected one of the plurality of potential layouts;

(ah) determine whether the current selected layout and determined physical properties of the analogue circuit or portion thereof meet the electrical requirements;

(ai) output a resulting initial design of the respective circuit portion; and wherein the primary design unit is further configured to:

(aj) receive a respective design for each circuit portion from each of the plurality of secondary design units; and
(ak) determine whether the respective design for each circuit portion from each of the plurality of secondary design units meets the electrical requirements and/or has the necessary physical properties;
in the event that the respective design for each circuit portion meets the electrical requirements:
(al) produce an output design for the analogue circuit or portion thereof; and
(am) produce the current analogue circuit design for the analogue circuit that satisfies the electrical requirements based on the respective designs for each circuit portion from each of the secondary design units.

The primary design unit may be further configured to:
simulate an analogue circuit based on the current analogue circuit design to produce at least one simulation output;
verify whether or not the analogue circuit meets the electrical requirements.

The primary design unit may further configured to:
when the analogue circuit meets the electrical requirements, output the generated design; and
when the analogue circuit does not meet the electrical requirements:
   select, another one of the plurality of potential layouts as the current selected layout, and repeat steps (ac) to (am).

Each of the plurality of secondary design units may be configured to adapt the design of the respective portion based on the simulated behaviour by adapting the design of the respective portion based on a difference between the simulated behaviour and the circuit performance requirements.

After at least an initial design of a given circuit portion has been completed by at least another one of the secondary design units, at least one of the secondary design units may be configured to adapt the current analogue circuit design based on a context of its corresponding circuit portion, the context comprising circuit performance requirements generated based on the completed design of the given circuit portion completed by the at least another one of the secondary design units.

In another aspect there is provided a method of designing an analogue circuit. The method comprises, at a design unit comprising a processor and a communications interface:
(a) controlling the communications interface to receive information representing electrical requirements for the analogue circuit or a portion thereof;
b) identifying, based on the received information, a plurality of potential layouts of the analogue circuit or portion thereof that satisfy the electrical requirements;
(c) selecting one of the plurality of potential layouts as the current selected layout, and determining physical properties of the analogue circuit or portion thereof based on the electrical requirements and the selected one of the plurality of potential layouts;
(d) determining whether the current selected layout and determined physical properties of the analogue circuit or portion thereof meet the electrical requirements;
(e) in the event that the current selected layout and determined physical properties of the analogue circuit or portion thereof meet the electrical requirements, producing an output design for the analogue circuit or portion thereof; and
(f) in the event that the selected layout and determined physical properties of the analogue circuit or portion thereof do not meet the electrical requirements:
   (f1) selecting another one of the plurality of potential layouts as the current selected layout and determining physical properties of the analogue circuit or portion thereof based on the electrical requirements and the selected one of the plurality of potential layouts;
   (f2) determining whether the current selected layout and determined physical properties of the analogue circuit or portion thereof meet the electrical requirements;
   (f3) and repeating steps (f1) and (f2) until the current selected layout and determined physical properties of the analogue circuit or portion thereof meet the electrical requirements, and then producing an output design for the analogue circuit or portion thereof.

Determining physical properties of the analogue circuit may comprise determining the physical size and/or spacing of components for implementing the electrical requirements.

Determining layout requirements for the analogue circuit may comprise identifying a layout technique from a list of possible layout techniques for implementing the electrical requirements. The list of possible layout techniques may comprise, for example: symmetrical, common centroid, and interdigitated.

Identifying, based on the received information, a plurality of potential layouts of the analogue circuit or portion thereof that satisfy the electrical requirements, may comprise ascribing functionality to portions of the analogue circuit based on the electrical requirements, and identifying potential analogue circuit layouts that provide the ascribed functionality. In other words, the circuit may be broken down into functional blocks and optimal layout technique for each of these functional blocks determined-for example, the analogue circuit design apparatus may determine that common centroid is the layout technique to apply if designing a differential pair, and may determine that current sources need to be interdigitated.

Identifying a plurality of potential layouts of the analogue circuit or portion therefore that satisfy the electrical requirements may comprise obtaining at least one layout for at least a portion of the analogue circuit via the communications interface. For example, the designer may specify which layout technique to apply to parts/portions or all of the analogue circuit that is to be designed. Advantageously, the analogue circuit design apparatus of embodiments of the claim allow the intent and context to be taken into account when designing the analogue circuit, which has not hitherto been possible.

The selection of the layout at step (c) and/or step (f1) may be based on a prioritisation of the plurality of potential layouts forming a prioritised list of potential layouts for the analogue circuit or portion thereof.

The determination of physical properties of the analogue circuit or a portion thereof at step (c) and/or step (f1) may be based on a prioritisation of the physical properties forming a prioritised list of physical properties for the analogue circuit or portion thereof.

The method may further comprise:

controlling the communications interface to receive information representing physical requirements for the analogue circuit or a portion thereof; and determining physical properties of the analogue circuit or portion thereof based on the electrical requirements, the physical requirements and the selected one of the plurality of potential layouts.

The method may further comprise:
(g) determining, for each current design for the analogue circuit, how well the current design meets the electrical requirements;
(h) selecting, a further analogue circuit design architecture as the current analogue circuit design architecture;
(i) repeating steps (b) and (f) to produce a plurality of produced output designs; and
(j) selecting and outputting a design for the analogue circuit from the plurality of produced analogue circuit designs that at least one of:
   (i) best meets the electrical requirements;
   (ii) makes the most efficient use of silicon; and
   (iii) has the lowest variation in electrical properties.

In some examples the design unit comprises a primary design unit and a secondary design unit, wherein the method comprises at the primary design unit:
dividing the analogue circuit or portion thereof into respective circuit portions based on the current selected layout;
providing electrical requirements for each circuit portion to at least one of a plurality of secondary design units;
   and at each of the plurality of secondary design units:
designing a respective circuit portion of the plurality of circuit portions based on the electrical requirements for that respective circuit portion provided by the primary design unit; and
outputting a resulting initial design of the respective circuit portion;
   further comprising, at the primary design unit:
receiving a respective design for each circuit portion from each of the plurality of secondary design units; and
determining whether the respective design for each circuit portion from each of the plurality of secondary design units meets the electrical requirements;
in the event that the respective design for each circuit portion meets the electrical requirements, producing an output design for the analogue circuit or portion thereof; and
producing the current analogue circuit design for the analogue circuit that satisfies the electrical requirements based on the respective designs for each circuit portion from each of the secondary design units.

In some examples the design unit comprises a primary design unit and a secondary design unit, wherein the method comprises at the primary design unit:
(aa) identifying, based on the received information, a plurality of potential layouts of the analogue circuit or portion thereof that satisfy the electrical requirements;
(ab) selecting one of the plurality of potential layouts as the current selected layout;
(ac) dividing the analogue circuit or portion thereof into respective circuit portions based on the current selected layout and/or physical properties;
(ad) providing electrical requirements for each circuit portion to at least one of a plurality of secondary design units;
   and at each of the plurality of secondary design units:
(ae) receiving information representing electrical requirements for the analogue circuit or a portion thereof;
(af) identifying, based on the received information, a plurality of potential layouts of the corresponding respective portion of the analogue circuit that satisfy the electrical requirements;
(ag) selecting one of the plurality of potential layouts as the current selected layout, and determining physical properties of the analogue circuit or portion thereof based on the electrical requirements and the selected one of the plurality of potential layouts;
(ah) determining whether the current selected layout and determined physical properties of the analogue circuit or portion thereof meet the electrical requirements;
(ai) outputting a resulting initial design of the respective circuit portion; and further comprising at the primary design unit:
(aj) receiving a respective design for each circuit portion from each of the plurality of secondary design units; and
(ak) determining whether the respective design for each circuit portion from each of the plurality of secondary design units meets the electrical requirements and/or has the necessary physical properties;
in the event that the respective design for each circuit portion meets the electrical requirements:
(al) producing an output design for the analogue circuit or portion thereof; and (
am) producing the current analogue circuit design for the analogue circuit that satisfies the electrical requirements based on the respective designs for each circuit portion from each of the secondary design units.

In some examples the design unit comprises a primary design unit and a secondary design unit, wherein the method comprises at the primary design unit:
(aa) identifying, based on the received information, a plurality of potential layouts of the analogue circuit or portion thereof that satisfy the electrical requirements;
(ab) selecting one of the plurality of potential layouts as the current selected layout, and determining physical properties of the analogue circuit or portion thereof based on the electrical requirements and the selected one of the plurality of potential layouts;
(ac) dividing the analogue circuit or portion thereof into respective circuit portions based on the current selected layout and/or physical properties;
(ad) providing electrical requirements and/or physical properties for each circuit portion to at least one of a plurality of secondary design units; and at each of the plurality of secondary design units:
(ae) receiving information representing electrical requirements for the analogue circuit or a portion thereof;
(af) identifying, based on the received information, a plurality of potential layouts of the corresponding respective portion of the analogue circuit that satisfy the electrical requirements;
(ag) selecting one of the plurality of potential layouts as the current selected layout, and determine physical properties of the analogue circuit or portion thereof based on the electrical requirements and the selected one of the plurality of potential layouts;
(ah) determining whether the current selected layout and determined physical properties of the analogue circuit or portion thereof meet the electrical requirements;
(ai) outputting a resulting initial design of the respective circuit portion; and wherein the method further comprises, at the primary design unit:
(aj) receiving a respective design for each circuit portion from each of the plurality of secondary design units; and
(ak) determining whether the respective design for each circuit portion from each of the plurality of secondary design units meets the electrical requirements and/or has the necessary physical properties;

in the event that the respective design for each circuit portion meets the electrical requirements:
(al) producing an output design for the analogue circuit or portion thereof; and
(am) producing the current analogue circuit design for the analogue circuit that satisfies the electrical requirements based on the respective designs for each circuit portion from each of the secondary design units.

The method may further comprise at the primary design unit:
simulating an analogue circuit based on the current analogue circuit design to produce at least one simulation output;
verifying whether or not the analogue circuit meets the electrical requirements.

The method may further comprise at the primary design unit:
outputting the generated design when the analogue circuit meets the electrical requirements; and
selecting, another one of the plurality of potential layouts as the current selected layout, and repeating steps (ac) to (am), when the analogue circuit does not meet the electrical requirements.

The method may further comprise, at each of the plurality of secondary design units, adapting the design of the respective portion based on the simulated behaviour by adapting the design of the respective portion based on a difference between the simulated behaviour and the circuit performance requirements.

After at least an initial design of a given circuit portion has been completed by at least another one of the secondary design units, the method may comprise, at at least one of the secondary design units, adapting the current analogue circuit design based on a context of its corresponding circuit portion, the context comprising circuit performance requirements generated based on the completed design of the given circuit portion completed by the at least another one of the secondary design units.

It will be understood that the method may further comprise fabricating an analogue circuit to the output design.

In another aspect there is provided a computer readable non-transitory storage medium comprising a program for a computer configured to cause a processor to perform any of the methods described above.

### DRAWINGS

Embodiments of the disclosure will now be described, by way of example only, with reference to the accompanying drawings, in which:

FIG. 1A shows a functional schematic diagram of an example analogue circuit;

FIG. 1B shows the functional schematic diagram of FIG. 1A divided into conceptual blocks;

FIG. 2 shows a functional schematic diagram of an example implementation of a computer-implemented hierarchical model for designing analogue circuits;

FIG. 3 shows a functional schematic view of another example implementation of a computer-implemented model for designing analogue circuits;

FIG. 4 shows portions of an analogue circuit designed by a computer-implemented hierarchical model, such as the model described with reference to any of FIGS. 1 to 3; and

FIG. 5 shows an example of a designed analogue circuit comprising the circuit portions of FIG. 4.

### SPECIFIC DESCRIPTION

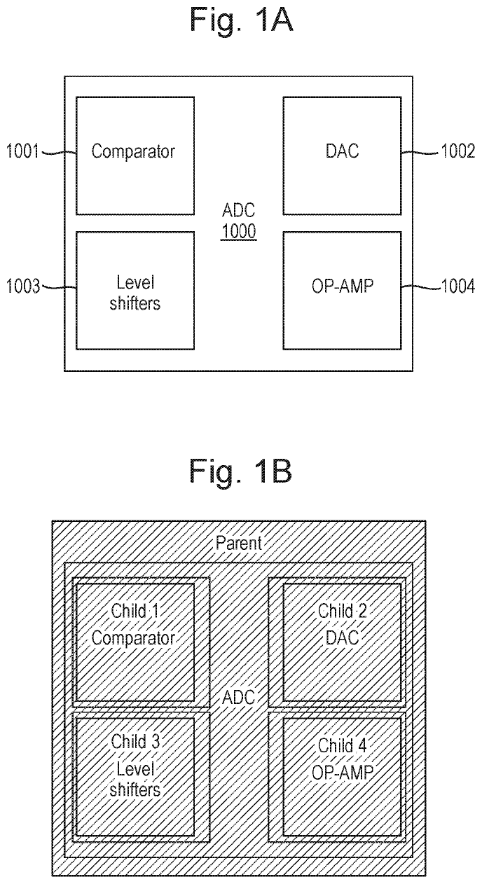

FIG. 1A shows a simplified functional schematic of an example analogue electronic circuit, which in this example is an analogue-to-digital converter (ADC) 1000. The analogue circuit may comprise several portions or components, such as a comparator 1001, a DAC 1002, level shifters 1003 and an OP-AMP 1004. While each portion or component may initially be considered in isolation, the context or environment in which that portion or component operates when applied in the circuit as a whole in situ may affect how that component/block operates, including, for example, the parasitics that the circuit portion, and the circuit as a whole, experiences. The design of analogue circuits has previously proved difficult to automate due to the complex feedback loops and mathematical relationships involved between different portions/components of the analogue circuit.

Embodiments of the claims relate to a method and system for automating the design of analogue circuits so that a more efficient circuit can be designed. In particular, embodiments of the claims relate to a method and system for automating the design of analogue circuits that is primarily dictated by the electrical requirements. This involves selecting potential analogue circuit design layouts first based on the electrical requirements, and then determining the physical properties of candidate circuits based on the electrical requirements and the selected layouts. The designed circuit is then tested to see whether, once the physical properties have been determined based on the layout, whether the candidate analogue circuit design meets the electrical requirements.

Advantageously this may mean that the analogue circuit can be designed in a way based on the designer's intent for that circuit.

The approach is counter-intuitive because selecting the most appropriate layout based first only on the electrical requirements may involve selecting a layout that is technically more complex but that is optimised and most efficient in meeting the electrical requirements required of it. By contrast, conventional approaches to analogue circuit design would tend to select the technically most simple design that satisfied the manufacturing requirements required of it.

Moreover, in certain embodiments the designer can choose which part of a circuit is to be preferentially treated (for example, they want a particular component to be used) and then embodiments may design other parts of the analogue circuit to follow on from that to provide the most efficient layout. The choice of which part of the circuit is to be preferentially treated may then influence the layout that could be selected-for example, the choice of preferentially treating a particular component may result in other components being selected to have the best width/aspect ratio/sizing to maintaining symmetry and/or best use of silicon. In addition, for peripheral components (e.g., ones that are not preferentially treated), embodiments may be configured to design these according to a particular default (for example, cheapest, most efficient, smallest etc.).

To implement this solution, the inventors in the present case have developed a computer-implemented model that delegates responsibility for designing portions or components of the analogue circuit to respective units or “blocks”. An example of this model is shown in

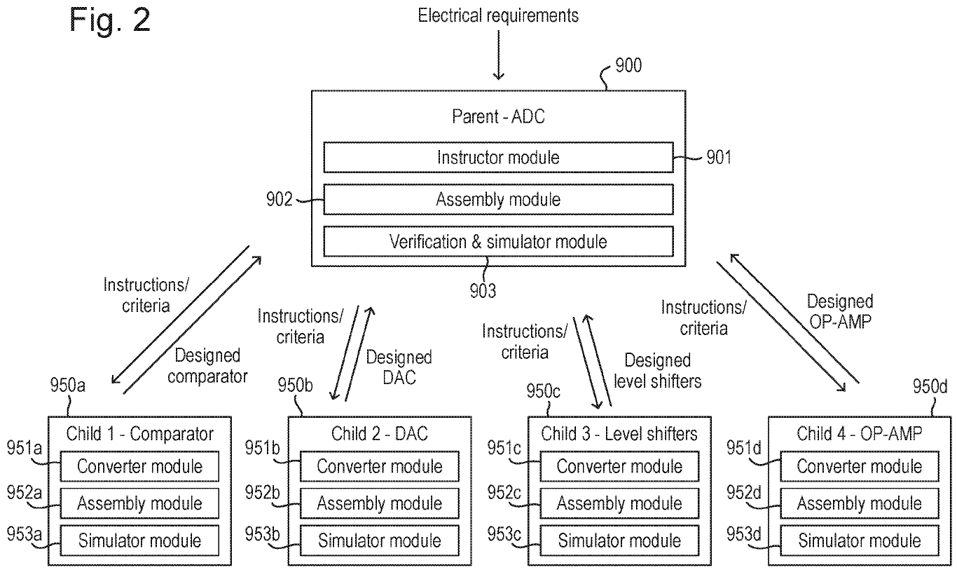

FIG. 2. Such a hierarchical model involves the use of a primary design unit, called a “parent block” 900, that acts as a controlling entity, and a number of secondary design units, called “child blocks” 950a-d that receive instructions from the primary design unit or parent block as to what they need to design.

As a controlling entity, the parent block 900 is configured to receive and process the technical requirements and obtain at least one circuit performance requirement and at least one manufacturing requirement for the analogue circuit to satisfy a specific set of manufacturing process related rules. The manufacturing process related rules may, as noted above, be based on electrical requirements.

The parent block 900 identifies, based on the electrical requirements, a plurality of potential analogue circuit design layouts. As described below, the parent block 900 may do this by employing a machine learning algorithm. The parent block 900 then selects, as a current selected analogue circuit design layout, an initial analogue circuit design layout from among the plurality of potential analogue circuit design layouts.

The model then produces a current design for the analogue circuit according to the selected layout. This is done by the parent block 900 instructing each secondary design unit or child block 950a-d to design a respective component or portion of the analogue circuit based on instructions received from the parent 900. The instructions may include the electrical requirements that the component or portion needs to meet (for example functional requirements) and in some examples may also comprise physical properties or requirements. The instructions and selection of child blocks 950a-d may depend on the selected layout chosen by the parent block 900, for example if another layout is selected by the parent block 900 then there may be a different number of child blocks 950a-d based on that selected layout.

The parent block 900 may do this by providing instructions that may comprise, for example, the respective electrical requirements for each circuit portion, to each of the child blocks 950a-d. Each child block 950a-d then designs a respective circuit portion of the plurality of circuit portions based on the electrical requirements (and optionally based on the selected layout) for that respective circuit portion provided by the parent block 900 and outputs a resulting initial design of the respective circuit portion. This resulting initial design of the respective circuit portion may comprise physical properties of the respective circuit portion. In this way the physical properties of the respective circuit portions are determined. The parent block 900 receives a respective design for each circuit portion from each of the plurality child blocks 950a-d and produces a current analogue circuit design based on the respective designs for each circuit portion. In some examples this assembly of the current analogue circuit design from the designed respective circuit portion may comprise further determining physical properties of the analogue circuit design (for example, the physical properties of the connections between respective components designed by the child blocks may be determined by the parent block 900 when assembling the respective circuit portions to create the overall analogue circuit design based on the electrical requirements and the selected layout).

In addition to the respective electrical requirements for each circuit portion, the instructions provided by the parent block 900 may also include information relating to the context of each component or portion of the circuit-in other words, what that portion or component of the circuit will experience when placed in the completed circuit in situ (in some examples the context may be provided as part of the electrical requirements, although in other examples it may be provided as something in addition to the electrical requirements). The context may comprise parameters and variables that the portion or component of the circuit experiences in use. The context of any given circuit portion or component may be generated based on simulating the performance of a circuit portion(s) or component(s) that interact with that given circuit portion or component, or even by simulating a completed circuit comprising that given circuit portion or component. For example, the parent block 900 may be configured to assemble a completed circuit from the portions or components designed by each child block 950a-d and simulate the assembled circuit's operation. The context of any given circuit portion or component may additionally or alternatively be generated based on mathematical calculations or extraction.

The parent block 900 may then determine whether the current selected layout and determined physical properties meets the electrical requirements. If it does, then an output design for the analogue circuit is produced. If it doesn't, then the process may be repeated with a different layout chosen as the current selected layout. In determining whether the current selected layout and determined physical properties meets the electrical requirements, the design of the completed analogue circuit may be tested to determine whether the current design will meet the electrical requirements. This testing may be performed by the parent block 900. The parent block 900 may do this by simulating an analogue circuit based on the current analogue circuit design to produce at least one simulation output, and then verifying whether or not the analogue circuit meets the electrical requirements.

As noted above, in the event that the current design for the analogue circuit is determined not to meet the electrical requirements, the parent block 900 selects a further analogue circuit design layout as the current selected analogue circuit design layout from the plurality of potential analogue circuit design layouts, wherein the selection of the further analogue circuit design layout is dependent on the electrical requirements. In some examples, the plurality of potential analogue circuit design layouts may be ordered in a hierarchy or ranking, for example as determined by a machine learning model, and the selection of the next analogue circuit design layout may be made based on the hierarchy or ranking.

The model then repeats the steps of producing a current design for the analogue circuit that satisfies the electrical requirements and testing the design of the completed analogue circuit to determine whether the current design will meet the electrical requirements. In the event that the current design does not meet the electrical requirements, this process is repeated (for example, optionally the next potential analogue circuit design layout may be selected from the ranked list of potential layouts). However, in the event that the current design does meet the electrical requirements, the parent block 900 outputs a design for the analogue circuit.

When testing the design of the analogue circuit, in some examples the parent block 900 determines, for the current design for the analogue circuit, if it is determined to meet the electrical requirements, how well the current design meets the electrical requirements. The parent block 900 may then select, a further analogue circuit design layout as the current selected analogue circuit design layout, and if it is determined to meet the electrical requirements, how well the current design meets the electrical requirements. This process may be repeated to produce a plurality of produced analogue circuit designs that all meet the electrical requirements but where some may be better suited/better satisfy the electrical requirements than others. The parent block 900 may then choose and output a design for the analogue circuit from the plurality of produced analogue circuit designs that best meets the electrical requirements.

When the parent block 900 selects an analogue circuit design layout, this may be based on a prioritisation of the plurality of potential layouts. For example, there may be a prioritised list of potential analogue circuit design layouts that have been identified to meet or as likely to meet the electrical requirements. The list could have been populated by the parent block 900, e.g., based on previous iterations of the design process, or could be supplied to the parent block 900 from elsewhere. For example, as will be described in more detail below, a machine learning algorithm may determine a prioritised list of analogue circuit design layouts based on the electrical requirements.

The computer-implemented hierarchical model may be iterative. Once the parent block 900 has instructed each child block 950a-d to design their respective portions, it may be that a degree of redesign of the circuit and its respective portions is required—for example to take into account features such as the parasitics and/or the context arising from the respective circuit portions designed by the other child blocks 950a-d. This may happen before the parent block 900 determines whether the current design will meet the at least one circuit performance requirement. For example, it may be that certain portions of the circuit may need to be adapted—for example due to the context provided by the other designed circuit portions and/or estimated parasitics that may be experienced either by a particular circuit portion or by the completed analogue circuit. The process of designing the circuit portions by each child block 950a-d may therefore be repeated to adapt the designs of one or more circuit portions to take into account, for example, the context and/or estimated parasitics in an attempt to mitigate and reduce them. This process of adapting designs of circuit portions may be repeated iteratively by the child blocks 950a-d, for example until any change in estimated parasitics caused by any adjustments to any other portions or components of the analogue circuit have been taken into account. For example, the process may iteratively repeat until any changes in estimated parasitics are less than a selected threshold level of change in parasitics.

In this context, it will be understood that in some examples the designer may preferentially choose which portion of the circuit is to be preferentially treated/designed first. For example, the parent block 900 may be instructed to instruct child blocks 950a-d to design a particular circuit portion first, and then design the other respective circuit portions once that particular has been designed. This may be called design level constraints. The design level constraints may include features such as cost, efficiency, PDK, foundry, the selection of particular sub-components etc.). As such, the parent block 900 may send, in addition to electrical requirements, design level constraints to the child blocks 950a-d, and the child blocks 950a-d may design their respective circuit portions based on the electrical requirements and the design level constraints. In such examples the respective circuit portions that are not preferentially treated/being part of the design level constraints may nonetheless be designed according to some other default, for example to achieve optimum efficiency, be the smallest in size etc. This default may be selected by the parent block 900 or may nonetheless be provided to the parent block 900 as part of the design level constraints.

The context and/or parasitics of any given circuit portion may be generated based on simulating the performance of a circuit portion(s) that interact with that given circuit portion, or even by simulating a completed circuit comprising that given circuit portion. For example, the parent block 900 may be configured to assemble a completed circuit from the portions designed by each child block 950a-d and simulate the assembled circuit's operation. The parasitics of any given circuit portion may additionally or alternatively be generated based on mathematical calculations or extraction. Additionally, or alternatively, the parasitics of any given circuit portion may be obtained by performing a lookup in a database of circuit designs and parasitics and/or predicted using a machine learning model. The parent block 900 may then verify whether or not the analogue circuit meets the electrical requirements. When the analogue circuit meets the electrical requirements, the parent block 900 may output the generated design. When the analogue circuit does not meet the electrical requirements, the parent block 900 may determine, for at least one affected circuit portion of the plurality of circuit portions, revised electrical requirements and/or design level constraints for that affected circuit portion based on the simulation output and the electrical requirements, and provide, to at least one corresponding child block 950a-d, the revised electrical requirements (and/or optionally design level constraints) for each affected circuit portion. The parent block 900 may in return receive a respective updated design of each affected circuit portion from the at least one corresponding child block 950a-d and update the current design of the analogue circuit with the respective updated design of each affected circuit portion. The parent block 900 may optionally then determine, for the updated current design for the analogue circuit, whether the current design will meet the electrical requirements, and optionally how well the current design meets the electrical requirements.

The present inventors have found that advantageously such a process and the use of an iterative hierarchical model allows the design of analogue circuits to be automated. As a result, advantageously this means that over-engineered analogue circuits and/or circuits with unacceptable parasitics can be avoided, and instead more efficient circuits designed and created. Furthermore, the present inventors have recognised that the design and selection of an analogue circuit in this way means that analogue circuits can be designed that are best suited to

As noted above, FIG. 1A shows an example analogue circuit architecture 1000 which in this example is an Analogue-to-Digital Converter (ADC). Conceptually the circuit architecture can be divided up into functional blocks corresponding to different portions or components of the circuit, for example based on their respective functionality. This layout of functional blocks or components can be said to represent the architecture. For example, an ADC may comprise a comparator 1001, a Digital-to-Analogue Converter (DAC) 1002, a plurality of level shifters 1003 and one or more OP-AMPs 1004. In the example shown in FIG. 1A the circuit can be divided up conceptually into blocks corresponding to these different portions or components that make up the architecture. For example, as shown in FIG. 1B the comparator may be divided up conceptually into a first “child block” 950a, the DAC into a second child block 950b, the level shifters into a third child block 950c, and the OP-AMP into a fourth child block 950d. The ADC as a whole may be conceptually classified as its own block (labelled “Parent” 900 in FIG. 1B). It will be understood that the ADC may itself form a conceptual block within a larger analogue circuit.

It will be understood that this division of the conceptual blocks may be performed by the parent block 900 (for example based on the electrical requirements and/or the current selected layout), and/or by a designer (for example being supplied as part of design level constraints).

If a circuit were to have a different layout, it will be understood that the circuit may have different components and a different arrangement and layout of these components-for example, the OP-AMP 1004 in one architecture may be replaced by two smaller OP-AMPs with lower gains in order to meet a specific set of manufacturing process related rules. This may be because the manufacturing process related rules that are dictated by one foundry/PDK means that the gain of the OP-AMP 1004 shown in FIG. 1A may not be supported, and so to achieve the same circuit performance requirement, the gain is achieved by replacing the single OP-AMP 1004 of FIG. 1A with two OP-AMPs each with a smaller gain.

In another example, one PDK (e.g. PDK 180) may support a voltage of 1.8V, but a second PDK (e.g. PDK 28) may support a voltage of 0.9V. For the PDK that supports a lower voltage (i.e. PDK 28) an analogue circuit design architecture may comprise an OTA-based amplifier with a source follower. While this architecture may also work for the higher voltage of PDK 180, such an architecture is not the optimum architecture to use for that

PDK-instead a folded cascode is more appropriate and efficient. The folded cascode architecture is more complex and therefore would be counter-intuitive to use if the model and process described herein were not used. That is why it can be said that the present application involves a counter-intuitive approach to analogue circuit design.

As noted above, in use in situ, there is an interplay between each of the different blocks of an analogue circuit. The interactions between these blocks in situ (which may include the parasitics that respective portions experience when placed in the completed circuit), and consequently the parameters and variables that each block experiences when placed in that circuit, affect the performance of that circuit. For example, the specification of the OP-AMP used in the circuit may depend on a number of parameters and variables arising from the selection and design of the comparator, the DAC and/or the level shifters, and the connections between them.

It will be understood that the physical properties may include variables such as length, number, finger width and multiplicity. It will also be understood that different layouts may comprise different layout techniques, such as symmetrical, common centroid, and interdigitated.

However, it will of course be appreciated that the design of an analogue circuit is an iterative process, whereby the selection and adjustment of one block may affect the context of another block, and so on. Thus, once the components of one block have been selected/adjusted to form a circuit portion, the components of another block may need to be adjusted or re-selected to take into account the parasitics and/or context experienced by the completed circuit/circuit portion in which that block is in. Such an iterative process is not practical to perform manually, is error-prone and can only be detected through communication.

As noted above, an example computer-implemented model for use in a method of automating the design of analogue circuits is shown in FIG. 2. FIG. 2 shows schematically the blocks shown in FIG. 1B and discussed above, and the interactions between the blocks.

In the example shown in FIG. 2, each block of the model is responsible for designing the components/functionality indicated by that block. In FIG. 2, child 1 950a is responsible for designing the comparator 1001, child 2 950b is responsible for designing the DAC 1002, child 3 950c is responsible for designing the level shifters 1003, and child 4 950d is responsible for designing the OP-AMP 1004. The parent block 900 is responsible for designing as a whole the ADC 1000, and delegates responsibility for designing the portions/components/functionality of the ADC to the child blocks 950a-d. In some examples the parent block 900 may select how many child blocks 950a-d are required, and the responsibility ascribed to each block. Although the child blocks 950a-d are shown in an order, it will be understood that this order is not necessarily representative of the order in which the portions of the circuit are designed. For example, the parent block 900 may instruct the child block 950d responsible for the OP-AMP to design that portion of the circuit first. In some examples the child blocks 950a-d may be configured to design the output first, and work backwards from there.

While each respective circuit portion may initially be designed by corresponding respective blocks in isolation, the context in which each respective circuit portion operates when applied in the circuit as a whole in situ may affect how both the respective circuit portions, as well as the circuit as a whole, operates. Therefore while the parent block may instruct each child block to design their respective portions, once an initial version of the designed circuit is assembled by the parent 900 from the portions or components designed by each child block 950a-d, it is likely that a degree of adaption or even redesign of the circuit 1000 and its portions or components is required to take into account the resulting parasitics and/or the context created by portions designed by the other child blocks 950a-d. As noted above, this will be an iterative process.

The parent block 900 is therefore configured to act as a controller, processing and handling the design process carried out by each of the child blocks. To perform this function, as shown in FIG. 2, the parent block 900 may comprise a number of different modules each configured to perform different functions as part of the design process. The parent block in FIG. 2 comprises an instructor module 901, an assembly module 902 and a verification and simulator module 903.

The instructor module 901 is configured to receive electrical requirements (and optionally design level constraints), and to convert these into a set of instructions/criteria that each child block 950a-d needs to meet when designing their respective components of the circuit. It is also configured to prepare and send the instructions to each child block 950a-d as to what they need to design and what criteria they need to meet in doing this. The instructions may also include the context of other designed portions of circuits designed by other child blocks and the wider context of the circuit in which that component or portion of the circuit is intended to be operated in. For example, the instructions and/or electrical requirements may be adjusted to take into account the context.

The assembly module 902 is configured to receive and collate all of the respective designed portions or components of the analogue circuit provided by each of the child blocks 950a-d, and to assemble a complete analogue circuit based on the respective designed portions or components. The completed analogue circuit may then be tested by the verification and simulator module 903.

The verification and simulator module 903 is configured to receive the designed components from each of the child blocks and to compare these to the electrical requirements to determine whether the designed portions or components are satisfactory or not. It may do this by simulating the functioning of the assembled components of the analogue circuit. The verification and simulation module 903 may determine whether the designed components/completed circuit design meets the electrical requirements. In so doing, it may also determine how well it meets these requirements, for example by allocating a score based on how closely the requirements are met and/or if they are exceeded. It may additionally or alternatively comprise a validation check to determine whether or not the circuit that is designed is valid in the sense that it can operate within certain technical limitations.

The verification and simulator module 903 may be configured to act as a “test bed” and simulate the functioning of the assembled components of the circuit. Such a simulation may yield, for example, the parasitics information and/or context information, as well as information relating to how well the components/completed circuit design meets the electrical requirements. For example, the verification and simulator module 903 may be configured to obtain performance information, for example relating to the context and parasitics that will be experienced in the analogue circuit if the analogue circuit were to include that designed circuit portion, by mathematically simulating the performance of at least one of (i) the designed circuit portion and (ii) a complete analogue circuit comprising the designed circuit portion, in a virtual test bench. Additionally, or alternatively, the verification and simulator module 903 may be configured to obtain performance information, for example relating to parasitics, that will be experienced in the analogue circuit if the analogue circuit were to include that designed circuit portion, by performing a lookup in a database of circuit designs and parasitics, for example by performing a lookup, in a database of circuit designs and parasitics, for similar generated designs. Additionally, or alternatively the verification and simulator module 903 may be configured to perform a lookup, in a database of circuit designs and parasitics, for at least one of the respective circuit portions for similar respective circuit portions, and obtain performance information, for example relating to parasitics experienced by the generated design based on the values of parasitics obtained via the lookup for the at least one of the respective circuit portions. In other examples the verification and simulator module 903 is configured to obtain performance information, for example relating to parasitics experienced by that generated design, by using a machine learning model to predict the performance of the circuit.

The verification and simulator module 903 may also be configured to populate a database of circuit designs, for example if the instructor module 901 instructs the child blocks 950a-d to repeat the process of designing circuit portions for example based on (new or adapted) corresponding electrical requirements a plurality of times. The database of circuit designs may also comprise information relating to how well a circuit design meets the electrical requirements.

Each child block 950a-d also comprises a number of different modules each configured to perform different functions as part of the design process. In the example shown in FIG. 2 each child block 950a-d comprises a converter module 951a-d, an assembly module 952a-d and a simulator module 953a-d. It will be understood that in some examples each child block 950a-d may further comprise additional modules for instructing tertiary design units or “grandchild” blocks, similar to the way in which the parent block 900 in FIG. 2 comprises modules such as the instructor module and verification module for instructing and verifying the design process from the child blocks 950a-d.

The converter module 951a-d of each child block 950a-d is configured to receive the instructions (for example, including electrical requirements) received from the parent block 900 and optionally the context of the circuit as a whole (for example, such as the layout, physical properties and/or design level constraints), as well as optionally the context of the other components of the circuit, and convert these into a set of requirements for designing a portion or component of the analogue circuit to meet those criteria. It will be understood that in some examples the context information may be provided and received as part of the instructions from the parent block (for example, in the form of electrical requirements), but in other examples it may be provided in addition to (e.g., separate from) the instructions/the electrical requirements.

The assembly module 952a-d is configured to select and/or design electronic components to satisfy the requirements being asked of it that meet the instructions/criteria dictated by the parent block and the context of the circuit as a whole and/or the context of the other components of the circuit. The assembly module 952a-d may also be configured to determine the physical properties of the respective circuit portion or component.

The simulator module 953a-d may also be configured to simulate how those components would run in situ to check/verify whether the designed portions or components designed by the assembly module are technically feasible. In some examples the simulator module 953a-d may also obtain information relating to the parasitics of the respective circuit portion that its block has designed, in a manner similar to the verification and simulator module 903 of the parent block 900 described above (it will be understood that in such examples the verification and simulator module 903 of the parent block 900 may not need to obtain information relating to parasitics as this may have already been performed by the simulator module 953a-d of each child block 950a-d).

In use, the parent block 900 receives electrical requirements for an analogue circuit 1000 to be designed, and in some examples also include optional design level constraints. In the example shown in FIG. 2, the parent block 900 receives a set of electrical requirements for an ADC to be designed.

The parent block 900 receives these requirements and the instructor module 901 converts these into a set of instructions/criteria. As part of this process, the instructor module 901 selects, as a current selected analogue circuit layout, an initial analogue circuit design layout from among a plurality of potential analogue circuit design layouts.

These instructions/criteria are then sent to each of the child blocks 950a-d. The instructor module 901 may send these instructions/criteria to each of the child blocks 950a-d in parallel (i.e., all at the same time) or in series (e.g., where the criteria are sent to child 1, then child 2, then child 3 and so on). In some examples the instructor module 901 may wait until it receives a designed circuit portion from the first child before sending instructions to the next child, and in some examples the instructor module may be configured to adjust the instructions (for example, by adjusting the electrical requirements) sent to the next child based on the designed circuit received from the preceding child-in other words based on the context (including, for example, the physical properties) of the designed circuit received from the preceding child.

In examples where instructions/criteria are sent to the child blocks 950a-d in series, the instructions/criteria may comprise means to distinguish which portions of the electrical requirements are relevant to which child blocks 950a-d-for example, the instructions/criteria may comprise headers or flags that identify whether or not a particular portion of the instructions/criteria is relevant to a child block 950a-d or not. These headers or flags may be determined by the parent block 900, and the instructions/criteria adjusted accordingly to incorporate them.

Each child block 950a-d receives these instructions/criteria from the parent block 900 and each respective converter module 951a-d converts these into a set of requirements for designing a portion or component of the analogue circuit to meet those instructions. The assembly module 952a-d receives these requirements and designs components/a portion of the circuit that meets these requirements. It will be understood that this design process may comprise a lookup in a database of known circuit designs (or portions therefore) and finding a circuit design that best matches the instructions/criteria. As part of this design process, the assembly module 952a-d of each child block may determine physical properties of the analogue circuit or portion thereof based on the electrical requirements and the selected one of the plurality of potential layouts.

The simulator module 953a-d then simulates how these components/portion of the circuit would work in situ to check whether the designed components/portion of the circuit designed by the assembly module is technically feasible and/or to verify whether or not the corresponding designed respective circuit portion meets the instructions/criteria (for example, whether the designed respective circuit portion meets the electrical requirements and/or design level constraints), for example based on the physical properties determined for that circuit portion. If the designed circuit portion meets its corresponding instructions/criteria, the child block 950a-d is then configured to send or output the designed portion or component of the circuit back to the parent 900. If the designed circuit portion does not meet its corresponding instructions/criteria, the child block 950a-d is then configured to adapt the design of its circuit portion and repeat the process.

Once the parent 900 receives all of the designed portions or components of the circuit back from all the child blocks 950a-d, including the determined physical properties of each of the designed portions or components, the assembly module 902 of the parent 900 then assembles the completed circuit (in this case the ADC) from the portions or components designed by each child block and the verification and simulation module 903 verifies whether the designed circuit (including the physical properties) meets the electrical requirements. It may do this by simulating how the assembled circuit performs and comparing this simulated performance to the electrical requirements. In so doing, it may also determine how well it meets these requirements, for example by allocating a score based on how closely the requirements are met and/or if they are exceeded. It may additionally or alternatively comprise a validation check to determine whether or not the circuit that is designed is valid in the sense that it can operate within certain technical limitations. It will be understood that in some examples this simulated performance of the completed analogue circuit design may be used to obtain the parasitics and/or the optional context information (e.g., for another design unit), and the parent 900 may adjust the instruction, for example the electrical requirements, based on the parasitics and/or optional context information obtained via the simulation of the completed analogue circuit design.

It will be understood that in some examples when the assembly module 902 of the parent 900 assembles the completed circuit, this may comprise determining physical properties of the assembled completed circuit. For example, even if physical properties of respective portions of the circuit have been provide by child blocks 950a-d, the assembly module 902 in assembling the circuit as a whole may also need to determine other physical properties (such as connections between respective components etc.) of the circuit. In such examples, the verification and simulation module 903 may verify whether the design circuit (including the physical properties of the circuit as a whole, as well as the physical properties of each respective component) meet the electrical requirements.

If the simulated performance of the designed circuit does not meet the electrical requirements (for example, a parameter of the simulated circuit is greater than a threshold level of different from a parameter dictated by the electrical requirements such as the parasitics being above a threshold level of parasitics) then the verification module 903 communicates this to the instructor module 901. The instructor module 901 may then select a further layout as the current layout.

In some examples the parent block 900 (for example, the verification module 903/instructor module 901), before a further analogue circuit design layout is selected, may be configured to determine which portion or component of the circuit is responsible for the circuit not meeting the electrical requirements (for example which portion is responsible for a large proportion of the parasitics), and in the event that a child block(s) 950a-d can be identified, the parent block 900 may be configured to send the revised instructions/electrical requirements only to the child block responsible for the offending portions or components of the circuit. However, in other examples the revised criteria may be sent back to all child blocks 950a-d. It will also be appreciated that in some examples the parent module 900 may determine that additional and/or alternative child blocks 950a-d and/or grandchild blocks may be required to design the relevant portions or components of the circuit, for example to meet the revised electrical requirements.

The process then continues in an iterative manner, where the converter module 951a-d of each child block 950a-d receives these revised or adapted instructions/electrical requirements from the parent block 900 and converts these into a new set of requirements for designing a portion or component of the analogue circuit to meet those adapted instructions/electrical requirements. The assembly module 952a-d receives these new requirements and designs components/a portion of the circuit that meets these requirements. The simulator module 953a-d may then simulate how the redesigned components/portion of the circuit would work in situ to check whether the designed components/portion of the circuit designed by the assembly module is technically feasible. The child block 950a-d is then configured to send the (re) designed components/portion of the circuit back to the parent 900.

Once the parent 900 receives all of the (re) designed components/portions of the circuit back from all the child blocks 950a-d, the parent 900 then assembles the completed circuit (in this case the ADC) from the components/portions designed by each child block and verifies whether the designed circuit meets the electrical requirements via the verification and simulator module 903 which may simulate how the assembled circuit performs and compares this simulated performance to the electrical requirements. When the analogue circuit meets the electrical requirements, the parent block 900 may output the generated design. When the analogue circuit does not meet the electrical requirements, the parent block 900 may determine, for at least one affected circuit portion of the plurality of circuit portions, revised instructions/criteria for that affected circuit portion based on the simulation output and the electrical requirements, and provide, to at least one corresponding child block 950a-d, the revised instructions/criteria for each affected circuit portion. The parent block 900 may in return receive a respective updated design of each affected circuit portion from the at least one corresponding child block 950a-d and update the current design of the analogue circuit with the respective updated design of each affected circuit portion.

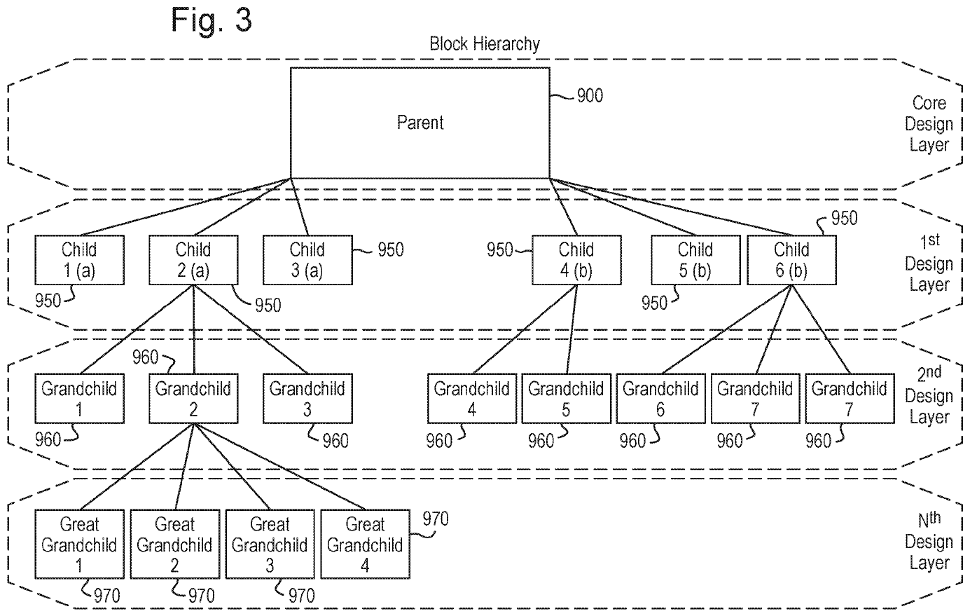

FIG. 3 illustrates a functional schematic view of another example implementation of a computer-implemented model for designing analogue circuits. The implementation of the model is in many respects similar to the model shown in FIG. 2 and the functionality described above for the parent 900 and child blocks 950a-d with respect to FIG. 2 may be ascribed to the parent and child blocks in FIG. 3. In addition, some of the functionality described in FIG. 2 with respect to a primary design unit or parent block 900 may be ascribed to a secondary design unit or child block 950a-d in FIG. 3 where that child block has tertiary design units or “grandchild” blocks beneath it, and so on.

In more detail, as shown in FIG. 3, the model hierarchy comprises a core design layer comprising a primary design unit or parent block. Although only one parent block 900 is shown in the core design layer in FIG. 3, it will be understood that in some examples there may be more than one parent block 900, for example where each parent block 900 operates in parallel. For example, each parent block 900 may be configured to design different aspects (e.g., functionally and/or structurally different from each other) of an analogue circuit.

Beneath the core design layer sits a first design layer. The first design layer comprises secondary design units or child blocks 950 coupled to the parent block 900 of the layer above (in this case the core design layer). In the example shown there are six child blocks, all coupled to the parent block of the core design layer. The child blocks 950 are grouped into two different groups: a first group comprising child blocks 1, 2 and 3; and a second group comprising child blocks 3, 4 and 5. Each child block 950 is coupled to the parent block 900. The two groups may represent different functional regions or areas of an analogue circuit which the parent block 900 instructs to be designed in parallel.

In the example shown, the child blocks 950 of the first group are coupled in parallel to the parent block 900 of the core design layer, and the child blocks 950 of the second group are coupled in parallel to the parent block 900 of the core design layer. The child blocks 950 may be grouped in this way to design different areas or aspects (e.g., functionally and/or structurally different from each other) of an analogue circuit. However, it will be understood that in some examples not all child blocks 950 of the first design layer need to be coupled in parallel to the parent block of the core design layer. For example, child blocks 1 and 3 of the first design layer may be coupled to the parent block 900 of the core design layer, and child block 2 of the first design layer may be coupled in series to child blocks 1 and 3 of the first design layer respectively.

The grouping of the child blocks 950 may be determined by the parent block 900 of the core design layer. For example, the parent block 900 may be configured to group the child blocks of the first design layer so as to design different aspects (e.g., functionally and/or structurally different from each other) of an analogue circuit. The parent block 900 of the core design layer may be configured to do this based on a determination of requirements from a customer specification.

Beneath the first design layer sits a second design layer. The second design layer comprises tertiary design units or grandchild blocks 1, 2, 3, 4, 5, 6, 7 and 8 960. The grandchild blocks 960 are coupled to child blocks of the layer above (the first design layer). Not every child block of the first design layer is coupled to a grandchild block of the second design layer. In the example shown, grandchild blocks 1, 2 and 3 of the second design layer are coupled in parallel to child block 2 of the first design layer. However, as described above for the child blocks 950 of the first design layer, it will be understood that in some examples not all grandchild blocks of the second design layer need to be coupled in parallel to the child block of the first design layer. For example, grandchild blocks 1 and 3 of the second design layer may be coupled to the child block 2 of the first design layer, and grandchild block 2 of the second design layer may be coupled in series to grandchild blocks 1 and 3 of the second design layer respectively.

Beneath the second design layer sits another (nth) design layer. The nth design layer comprises greatgrandchild blocks 1, 2, 3 and 4 970. The greatgrandchild blocks 970 are coupled to grandchild blocks 960 of the layer above (the second design layer) in much the same way that the grandchild blocks 960 of the second design layer are coupled to the child blocks 950 of the first design layer. It will therefore be understood that there may a plurality of further design layers sitting below the second design layer each comprising their own blocks coupled to blocks of the layer above.

The structure of the block hierarchy shown in FIG. 3 is such that the blocks of different layers of the model are configured to design aspects or portions of an analogue circuit at different levels of complexity. For example, the parent block 900 may be configured to design a complete analogue circuit, the child blocks 950 configured to design functional components of the analogue circuit (such as an op-amp, AC/DC converter, level shifters, comparators, voltage regulators, power switches etc.), and grandchild block 960 configured to design the components of that functional component (e.g., the arrangement of resistors, transistors, capacitors, diodes, inductors etc. for that component).

The parent block 900 (of the core design layer) may be configured to determine the level of complexity a block of a selected layer is configured to design, and/or the blocks of one layer may be configured to determine the level of complexity that the blocks of the layer below are configured to design.

Additionally, or alternatively, the structure of the block hierarchy shown in FIG. 3 is such that the blocks of different layers of the model are configured to design aspects or portions of an analogue circuit based on different functional or structural requirements. For example, one layer may comprise blocks configured to design aspects or portions of an analogue circuit based on one functional requirement (e.g., size) and another layer may comprise blocks configured to design another functional requirement (e.g., current or voltage).

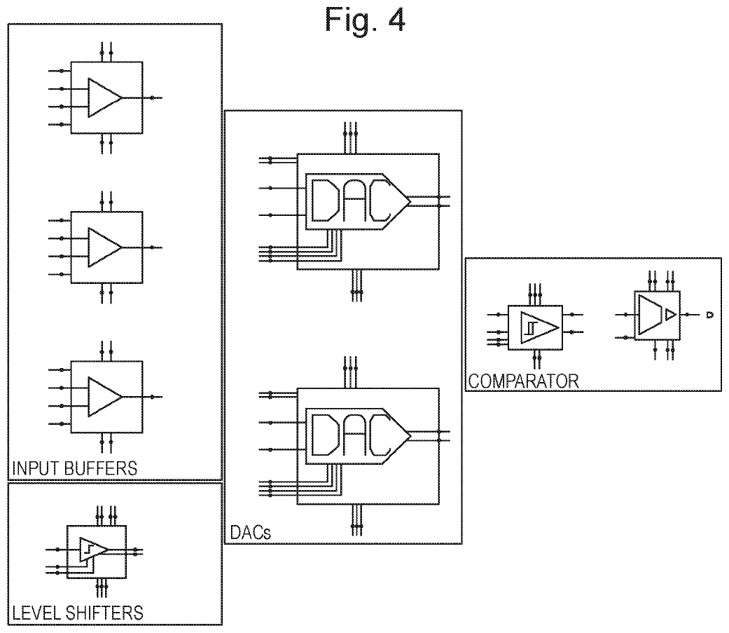

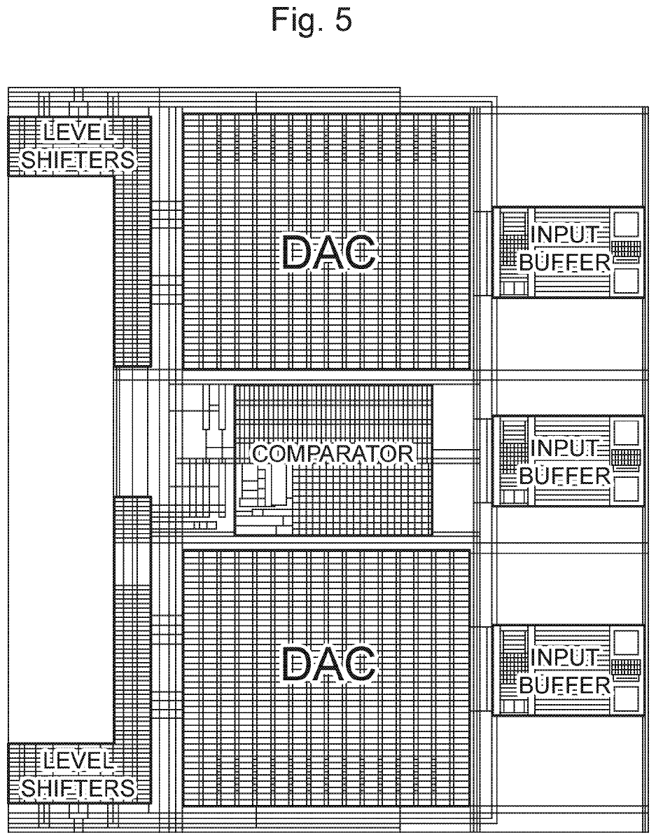

FIG. 4 shows Input Buffers, Level Shifters, DACs and a Comparator. Each of these may form a portion of a completed analogue circuit, such as the completed ADC shown in FIG. 5.

The examples shown in FIGS. 4 and 5 have been designed using a computer-implemented hierarchical model as described above. A parent block (or primary design unit) is responsible for designing the overall ADC, with child blocks (or secondary design units) being responsible, respectively, for each of the Input Buffers, Level Shifters, DACs and the Comparator. The parent block receives electrical requirements from a user and converts these into circuit performance requirements which are used by each child block to design their respective portions of the circuit. The context of other portions of the circuit is considered and used by the child blocks in designing their respective portions of the circuit. The model is also iterative in that once the parent block 900 has instructed each child block 950a-d to design their respective portions or components, a degree of redesign of the circuit and its portions is performed so that the context provided by the other portions of the circuit is used in designing the respective circuit portions and the circuit as a whole. As described above, each child block and/or parent block may also perform validation/verification to determine whether the designed portions/complete circuit meets the technical requirements asked of it.

In the designed circuit shown in FIG. 5, the reason there are two DACs is that the circuit provides a differential ADC. The reason there are multiple (in the example shown, three) input buffers is that two are used to buffer two inputs and the reference is also buffered as an input.

As noted above, the analogue circuit design apparatus may make use of a machine learning model to identify, select and/or prioritise potential analogue circuit design architectures.

The machine learning model may comprise a neural network. The neural network may comprise at least one of a deep residual network, a highway network, a densely connected network and a capsule network.

For any such type of network, the network may comprise a plurality of different neurons, which are organised into different layers. Each neuron is configured to receive input data, process this input data and provide output data. Each neuron may be configured to perform a specific operation on its input, e.g., this may involve mathematically processing the input data. The input data for each neuron may comprise an output from a plurality of other preceding neurons. As part of a neuron's operation on input data, each stream of input data (e.g., one stream of input data for each preceding neuron which provides its output to the neuron) is assigned a weighting. That way, processing of input data by a neuron comprises applying weightings to the different streams of input data so that different items of input data will contribute more or less to the overall output of a neuron.

Adjustments to the value of the inputs for a neuron, e.g., as a consequence of the input weightings changing, may result in a change to the value of the output for that neuron. The output data from each neuron may be sent to a plurality of subsequent neurons.

The neurons are organised in layers. Each layer comprises a plurality of neurons which operate on data provided to them from the output of neurons in preceding layers. Within each layer there may be a large number of different neurons, each of which applies a different weighting to its input data and performs a different operation on its input data. The input data for all of the neurons in a layer may be the same, and the output from the neurons will be passed to neurons in subsequent layers.

The exact routing between neurons in different layers forms a major difference between capsule networks and deep residual networks (including variants such as highway networks and densely connected networks).

For a residual network, layers may be organised into blocks, such that the network comprises a plurality of blocks, each of which comprises at least one layer. For a residual network, output data from one layer of neurons may follow more than one different path. For conventional neural networks (e.g., convolutional neural networks), output data from one layer is passed into the next layer, and this continues until the end of the network so that each layer receives input from the layer immediately preceding it and provides output to the layer immediately after it. However, for a residual network, a different routing between layers may occur. For example, the output from one layer may be passed on to multiple different subsequent layers, and the input for one layer may be received from multiple different preceding layers.

In a residual network, layers of neurons may be organised into different blocks, wherein each block comprises at least one layer of neurons. Blocks may be arranged with layers stacked together so that the output of a preceding layer (or layers) feeds into the input of the next block of layers. The structure of the residual network may be such that the output from one block (or layer) is passed into both the block (or layer) immediately after it and at least one other later subsequent block (or layer). Shortcuts may be introduced into the neural network which pass data from one layer (or block) to another whilst bypassing other layers (or blocks) in between the two. This may enable more efficient training of the network, e.g., when dealing with very deep networks, as it may enable problems associated with degradation to be addressed when training the network (which is discussed in more detail below). The arrangement of a residual neural network may enable branches to occur such that the same input provided to one layer, or block of layers, is provided to at least one other layer, or block of layers (e.g., so that the other layer may operate on both the input data and the output data from the one layer, or block of layers). This arrangement may enable a deeper penetration into the network when using back propagation algorithms to train the network. For example, this is because during learning, layers, or blocks of layers, may be able to take as an input, the input of a previous layer/block and the output of the previous layer/block, and shortcuts may be used to provide deeper penetration when updating weightings for the network.

For a capsule network, layers may be nested inside of other layers to provide ‘capsules’. Different capsules may be adapted so that they are more proficient at performing different tasks than other capsules. A capsule network may provide dynamic routing between capsules so that for a given task, the task is allocated to the most competent capsule for processing that task. For example, a capsule network may avoid routing the output from every neuron in a layer to every neuron in the next layer. A lower-level capsule is configured to send its input to a higher level (subsequent) capsule which is determined to be the most likely capsule to deal with that input. Capsules may predict the activity of higher layer capsules. For example, a capsule may output a vector, for which the orientation represents properties of an object in question. In response, each subsequent capsule may provide, as an output, a probability that the object that capsule is trained to identify is present in the input data. This information (e.g., the probabilities) can be fed back to the capsule, which can then dynamically determine routing weights, and forward the input data to the subsequent capsule most likely to be the relevant capsule for processing that data.

For either type of neural network, there may be included a plurality of different layers which have different functions. The neural network may include at least one convolutional layer configured to convolve input data across its height and width. The neural network may also have a plurality of filtering layers, each of which comprises a plurality of neurons configured to focus on and apply filters to different portions of the input data. Other layers may be included for processing the input data such as pooling layers (to introduce non-linearity) such as maximum pooling and global average pooling, Rectified Linear Units layer (ReLU) and loss layers, e.g., some of which may include regularization functions. The final block of layers may receive input from the last output layer (or more layers if there are branches present). The final block may comprise at least one fully connected layer.

The final output layer may comprise a classifier, such as a softmax, sigmoid or tanh classifier. Different classifiers may be suitable for different types of output; for example, a sigmoid classifier may be suitable where the output is a binary classifier. The neural network of the present disclosure may be configured to predict which analogue circuit design architecture is likely to work based on the electrical requirements for the analogue circuit. The output of the neural network may provide an indication of a probability that an analogue circuit design layout will be suitable for the electrical requirements. For example, the output of the neural network may provide an indication of a probability that an analogue circuit design layout will meet the electrical requirements. The circuit design architectures may be prioritised or ranked according to their determined probability, so that, for example, when a parent block as described above selects a circuit design layout from among a plurality of circuit design layouts that will satisfy the electrical requirements, the one that is selected first the one that has been determined to have the highest probability of meeting the electrical requirements.

It will be understood in the context of the present disclosure that a non-exhaustive list of example analogue parameters that may form basis of the criteria include: Noise tolerance;

Power Supply Rejection Ratio (PSRR); Common Mode Range-Input (Input CMR); Common Mode Range-Output (Output CMR); Linearity; Maximum Offset; Bandwidth; Minimum Slew Rate; Intrinsic Delay; Minimum phase margin; Active Power consumption; Static power consumption; IP3 point; Filter centre-frequency; Filter band-pass range; Load Step response; Line step response; Output Accuracy; Noise figure; Calibration range; Noise floor; SNR; ENOB; SINAD; Output frequency range; Jitter—ptp; Jitter—RMS; Output ripple ptp; Total Harmonic Distortion; Start-up time; Channel isolation; Reference voltage; Gain error; Offset error; Gain drift.

It will also be understood that the design units (such as the primary, secondary and tertiary design units) may be implemented in software or hardware, for example as dedicated circuitry. For example, the design units may be implemented as part of a computer system. The computer system may include a bus or other communication mechanism for communicating information data, signals, and information between various components of the computer system. The components may include an input/output (I/O) component that processes a user (i.e., sender, recipient, service provider) action, such as selecting keys from a keypad/keyboard, selecting one or more buttons or links, etc., and sends a corresponding signal to the bus. The I/O component may also include an output component, such as a display and a cursor control (such as a keyboard, keypad, mouse, etc.). A transceiver or network interface may transmit and receives signals between the computer system and other devices, such as another user device, a merchant server, or a service provider server via a network. In one embodiment, the transmission is wireless, although other transmission mediums and methods may also be suitable. A processor, which can be a micro-controller, digital signal processor (DSP), or other processing component, processes these various signals, such as for display on the computer system or transmission to other devices via a communication link. The processor may also control transmission of information, such as cookies or IP addresses, to other devices.

The components of the computer system may also include a system memory component (e.g., RAM), a static storage component (e.g., ROM), and/or a disk drive (e.g., a solid-state drive, a hard drive). The computer system performs specific operations by the processor and other components by executing one or more sequences of instructions contained in the system memory component.

Logic may be encoded in a computer readable medium, which may refer to any medium that participates in providing instructions to a processor for execution. Such a medium may take many forms, including but not limited to, non-volatile media, volatile media, and transmission media. In various implementations, non-volatile media includes optical or magnetic disks, volatile media includes dynamic memory, such as a system memory component, and transmission media includes coaxial cables, copper wire, and fiber optics. In one embodiment, the logic is encoded in non-transitory computer readable medium. In one example, transmission media may take the form of acoustic or light waves, such as those generated during radio wave, optical, and infrared data communications.

Some common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, or any other medium from which a computer is adapted to read.

In various embodiments of the present disclosure, execution of instruction sequences to practice the present disclosure may be performed by a computer system. In various other embodiments of the present disclosure, a plurality of computer systems 600 coupled by a communication link to a network (e.g., such as a LAN, WLAN, PTSN, and/or various other wired or wireless networks, including telecommunications, mobile, and cellular phone networks) may perform instruction sequences to practice the present disclosure in coordination with one another.

It will also be understood that aspects of the present disclosure may be implemented using hardware, software, or combinations of hardware and software. Also, where applicable, the various hardware components and/or software components set forth herein may be combined into composite components comprising software, hardware, and/or both without departing from the spirit of the present disclosure. Where applicable, the various hardware components and/or software components set forth herein may be separated into sub-components comprising software, hardware, or both without departing from the scope of the present disclosure. In addition, where applicable, it is contemplated that software components may be implemented as hardware components and vice-versa.

Software in accordance with the present disclosure, such as program code and/or data, may be stored on one or more computer readable mediums. It is also contemplated that software identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

The various features and steps described herein may be implemented as systems comprising one or more memories storing various information described herein and one or more processors coupled to the one or more memories and a network, wherein the one or more processors are operable to perform steps as described herein, as non-transitory machine-readable medium comprising a plurality of machine-readable instructions which, when executed by one or more processors, are adapted to cause the one or more processors to perform a method comprising steps described herein, and methods performed by one or more devices, such as a hardware processor, user device, server, and other devices described herein.

In the context of the present disclosure other examples and variations of the apparatus and methods described herein will be apparent to a person of skill in the art.

1. An analogue circuit design apparatus, the apparatus comprising at least one design unit comprising a processor and a communications interface, the processor being configured to:
(a) control the communications interface to receive information representing electrical requirements for the analogue circuit or a portion thereof:
(b) identify, based on the received information, a plurality of potential layouts of the analogue circuit or portion thereof that satisfy the electrical requirements:
(c) select one of the plurality of potential layouts as the current selected layout, and determine physical properties of the analogue circuit or portion thereof based on the electrical requirements and the selected one of the plurality of potential layouts:
(d) determine whether the current selected layout and determined physical properties of the analogue circuit or portion thereof meet the electrical requirements:
(e) in the event that the current selected layout and determined physical properties of the analogue circuit or portion thereof meet the electrical requirements, produce an output design for the analogue circuit or portion thereof; and
(f) in the event that the selected layout and determined physical properties of the analogue circuit or portion thereof do not meet the electrical requirements:
(f1) select another one of the plurality of potential layouts as the current selected layout and determine physical properties of the analogue circuit or portion thereof based on the electrical requirements and the selected one of the plurality of potential layouts:
(f2) determine whether the current selected layout and determined physical properties of the analogue circuit or portion thereof meet the electrical requirements:
(f3) and repeat steps (f1) and (f2) until the current selected layout and determined physical properties of the analogue circuit or portion thereof meet the electrical requirements, and then produce an output design for the analogue circuit or portion thereof.

2. The analogue circuit design apparatus of claim 1, wherein determining physical properties of the analogue circuit comprises determining the physical size and/or spacing of components for implementing the electrical requirements.

3. The analogue circuit design apparatus of claim 1 wherein determining layout requirements for the analogue circuit comprises identifying a layout technique from a list of possible layout techniques for implementing the electrical requirements, wherein the list of possible layout techniques comprises: symmetrical, common centroid, and interdigitated.

4. (canceled)

5. The analogue circuit design apparatus of claim 1 wherein:
identifying, based on the received information, a plurality of potential layouts of the analogue circuit or portion thereof that satisfy the electrical requirements, comprises ascribing functionality to portions of the analogue circuit based on the electrical requirements, and identifying potential analogue circuit layouts that provide the ascribed functionality.

6. The analogue circuit design apparatus of claim 1 wherein identifying a plurality of potential layouts of the analogue circuit or portion thereforethereof that satisfy the electrical requirements comprises obtaining at least one layout for at least a portion of the analogue circuit via the communications interface.

7. The analogue circuit design apparatus of claim 1 wherein the selection of the layout at step (c) and/or step (f1) is based on a prioritisation of the plurality of potential layouts forming a prioritised list of potential layouts for the analogue circuit or portion thereof.

8. The analogue circuit design apparatus of claim 1 wherein the determination of physical properties of the analogue circuit or a portion thereof at step (c) and/or step (f1) is based on a prioritisation of the physical properties forming a prioritised list of physical properties for the analogue circuit or portion thereof.

9. The analogue circuit design apparatus of claim 1, wherein the processor is further configured to:
control the communications interface to receive information representing physical requirements for the analogue circuit or a portion thereof; and
determine physical properties of the analogue circuit or portion thereof based on the electrical requirements, the physical requirements and the selected one of the plurality of potential layouts.

10. The analogue circuit design apparatus of claim 1 wherein the processor is further configured to:
(g) determine, for each current design for the analogue circuit, how well the current design meets the electrical requirements:
(h) select, a further analogue circuit design architecture as the current analogue circuit design architecture:
(i) repeat steps (b) and (f) to produce a plurality of produced output designs; and
(j) select and output a design for the analogue circuit from the plurality of produced analogue circuit designs that at least one of:
(i) best meets the electrical requirements:
(ii) makes the most efficient use of silicon; and
(iii) has the lowest variation in electrical properties.

11.-17. (canceled)

18. A method of designing an analogue circuit, the method comprising, at a design unit comprising a processor and a communications interface:
(a) controlling the communications interface to receive information representing electrical requirements for the analogue circuit or a portion thereof:
(b) identifying, based on the received information, a plurality of potential layouts of the analogue circuit or portion thereof that satisfy the electrical requirements:
(c) selecting one of the plurality of potential layouts as the current selected layout, and determining physical properties of the analogue circuit or portion thereof based on the electrical requirements and the selected one of the plurality of potential layouts:
(d) determining whether the current selected layout and determined physical properties of the analogue circuit or portion thereof meet the electrical requirements:
(e) in the event that the current selected layout and determined physical properties of the analogue circuit or portion thereof meet the electrical requirements, producing an output design for the analogue circuit or portion thereof; and
(f) in the event that the selected layout and determined physical properties of the analogue circuit or portion thereof do not meet the electrical requirements:
(f1) selecting another one of the plurality of potential layouts as the current selected layout and determining physical properties of the analogue circuit or portion thereof based on the electrical requirements and the selected one of the plurality of potential layouts:
(f2) determining whether the current selected layout and determined physical properties of the analogue circuit or portion thereof meet the electrical requirements:
(f3) and repeating steps (f1) and (f2) until the current selected layout and determined physical properties of the analogue circuit or portion thereof meet the electrical requirements, and then producing an output design for the analogue circuit or portion thereof.

19. The method of claim 18, wherein determining physical properties of the analogue circuit comprises determining the physical size and/or spacing of components for implementing the electrical requirements.

20. The method of claim 18 wherein determining layout requirements for the analogue circuit comprises identifying a layout technique from a list of possible layout techniques for implementing the electrical requirements, wherein the list of possible layout techniques comprises: symmetrical, common centroid, and interdigitated.

21. (canceled)

22. The method of claim 18 wherein:
identifying, based on the received information, a plurality of potential layouts of the analogue circuit or portion thereof that satisfy the electrical requirements, comprises ascribing functionality to portions of the analogue circuit based on the electrical requirements, and identifying potential analogue circuit layouts that provide the ascribed functionality.

23. The method of claim 18 wherein identifying a plurality of potential layouts of the analogue circuit or portion thereof that satisfy the electrical requirements comprises obtaining at least one layout for at least a portion of the analogue circuit via the communications interface.

24. The method of claim 18 wherein the selection of the layout at step (c) and/or step (f1) is based on a prioritisation of the plurality of potential layouts forming a prioritised list of potential layouts for the analogue circuit or portion thereof.

25. The method of claim 18 wherein the determination of physical properties of the analogue circuit or a portion thereof at step (c) and/or step (f1) is based on a prioritisation of the physical properties forming a prioritised list of physical properties for the analogue circuit or portion thereof.

26. The method of claim 18, further comprising:
controlling the communications interface to receive information representing physical requirements for the analogue circuit or a portion thereof; and
determining physical properties of the analogue circuit or portion thereof based on the electrical requirements, the physical requirements and the selected one of the plurality of potential layouts.

27. The method of claim 18, further comprising:
(g) determining, for each current design for the analogue circuit, how well the current design meets the electrical requirements:
(h) selecting, a further analogue circuit design architecture as the current analogue circuit design architecture:
(i) repeating steps (b) and (f) to produce a plurality of produced output designs: and
(j) selecting and outputting a design for the analogue circuit from the plurality of produced analogue circuit designs that at least one of:
(i) best meets the electrical requirements:
(ii) makes the most efficient use of silicon: and
(iii) has the lowest variation in electrical properties.

28.-34. (canceled)

35. A computer readable non-transitory storage medium comprising a program for a computer configured to cause a processor to perform the method of claim 18.
